(19) United States
(12) Patent Application Publication
(10) Pub. No.: US 2026/0227178 A1
(43) Pub. Date: Aug. 6, 2026

(54) EQUIPMENT FOR PREDICTING WAFER DEFORMATION

(71) Applicant: SAMSUNG ELECTRONICS CO., LTD., Suwon-si (KR)

(72) Inventors: Sangyoung SEO, Suwon-si (KR); Jinkook PARK, Suwon-si (KR); Woncheol LEE, Suwon-si (KR); Young-Seok KIM, Suwon-si (KR); Youngil KIM, Suwon-si (KR); Chunghun PARK, Suwon-si (KR)

(73) Assignee: SAMSUNG ELECTRONICS CO., LTD., Suwon-si (KR)

(21) Appl. No.: 19/301,504

(22) Filed: Aug. 15, 2025

(30) Foreign Application Priority Data
Feb. 4, 2025 (KR) 10-2025-0014031

(51) Int. Cl. G01B 11/16

(52) U.S. Cl. CPC G01B 11/16

(57) ABSTRACT

An equipment for predicting wafer deformation includes a transport unit that transports a wafer; a sensor unit that recognizes a plurality of edge points of the wafer being transported by the transport unit; and a control unit that projects positions of the plurality of edge points of the wafer recognized by the sensor unit onto a coordinate plane, and predicts a plane form of the wafer based on the positions of the plurality of edge points of the wafer projected onto the coordinate plane.

### CROSS-REFERENCE TO RELATED APPLICATION

This application claims priority to and the benefit of Korean Patent Application No. 10-2025-0014031 filed with the Korean Intellectual Property Office on February 4, 2025, the entire contents of which are incorporated herein by reference.

### BACKGROUND OF THE INVENTION

### a. Field of the Invention

The present disclosure relates to an equipment for predicting wafer deformation.

### b. Description of the Related Art

During a manufacturing process of semiconductor chips, deformations (warpages) such as bow and warp may occur to the wafer due to temperature differences, etc. When the wafer is moved to a warpage measurement equipment to measure the warpage of the wafer, a lot of TAT (Turn Around Time) is required due to the movement, input, alignment, and measurement of the wafer, which may cause a decrease in productivity. To minimize the decrease in productivity, a method of measuring the warpage of only some of the wafers could be considered, but in this case, the deformation of the wafers due to warpage may not be perfectly detected, and thus, the wafer may be fractured. If the inside of the equipment is contaminated due to the fractured wafer, it may have a significant impact on productivity due to a production stoppage.

### SUMMARY OF THE INVENTION

In one aspect, the present disclosure attempts to provide an equipment for predicting wafer deformation capable of predicting wafer deformation without increased time and cost due to additional processes.

In another aspect, the present disclosure attempts to provide an equipment for predicting wafer deformation that may predict a deformation for all wafers and selectively input only undeformed wafers into a process.

In another aspect, the present disclosure attempts provide an equipment for predicting wafer deformation that may prevent wafer fracture and equipment contamination resulting therefrom.

As one embodiment, the present disclosure provides an equipment for predicting wafer deformation comprising: a transport unit that transports a wafer; a sensor unit that recognizes a plurality of edge points of the wafer being transported by the transport unit; and a control unit that projects positions of the plurality of edge points of the wafer recognized by the sensor unit onto a coordinate plane, and predicts a plane form of the wafer based on the positions of the plurality of edge points of the wafer projected onto the coordinate plane.

As another embodiment, the present disclosure provides an equipment for predicting wafer deformation comprising: a transport unit that transports a wafer to a process chamber and returns the wafer discharged from the process chamber; a sensor unit that recognizes a plurality of edge points of the wafer before process during transport of the wafer by the transport unit and a plurality of edge points of the wafer after process during return of the wafer by the transport unit; and a control unit that projects positions of the plurality of pre-process edge points of the wafer recognized by the sensor unit onto a coordinate plane and predicts a plane form of the wafer before process based on the positions of the plurality of pre-process edge points of the wafer projected onto the coordinate plane, and projects positions of the plurality of post-process edge points of the wafer recognized by the sensor unit onto the coordinate plane and predicts a plane form of the wafer after process based on the positions of the plurality of post-process edge points of the wafer projected onto the coordinate plane.

As another embodiment, the present disclosure provides an equipment for predicting wafer deformation comprising: a transport unit that moves a wafer in a first direction, moves the wafer in a second direction opposite to the first direction, and then transports the wafer in the first direction; a sensor unit that recognizes a plurality of first edge points of the wafer during the wafer is moved in the first direction by the transport unit, and recognizes a plurality of second edge points of the wafer during the wafer is moved in the second direction by the transport unit; and a control unit that projects positions of the plurality of first edge points of the wafer and the plurality of second edge points of the wafer recognized by the sensor unit onto a coordinate plane, and predicts a plane form of the wafer based on the positions of the plurality of first edge points of the wafer and the plurality of second edge points of the wafer projected onto the coordinate plane; wherein the wafer passes through the sensor unit during moving in the first direction by the transport unit and during moving in the second direction by the transport unit.

As another embodiment, the present disclosure provides a method for predicting wafer deformation, comprising: a step of passing a wafer through a sensor unit; a step of projecting positions of a plurality of edge points of the wafer recognized by the sensor unit onto a planar coordinate; and a step of predicting a plane form of the wafer based on the positions of the plurality of edge points of the wafer projected onto the coordinate plane.

According to one aspect of the present disclosure, an equipment for predicting wafer deformation capable of predicting wafer deformation without increased time and cost due to additional processes may be provided.

According to another aspect of the present disclosure, an equipment for predicting wafer deformation that may predict a deformation for all wafers and selectively input only undeformed wafers into a process may be provided.

According to another aspect of the present disclosure, an equipment for predicting wafer deformation that may prevent wafer fracture and equipment contamination resulting therefrom may be provided.

### BRIEF DESCRIPTION OF THE DRAWINGS

FIG. 1, FIG. 2 and FIG. 3 illustrate an operation example of an equipment for predicting wafer deformation according to an embodiment.

FIG. 4 and FIG. 5 show the positions of edge points of the wafer projected onto a coordinate plane.

FIG. 6 shows a predicted plane form of the wafer and a derived exemplary feature value.

FIG. 7 and FIG. 8 illustrate a method for recognizing edge points of the wafer by a sensor unit according to an embodiment.

FIG. 9 shows exemplary shapes of wafers and their projection surfaces.

FIG. 10 is a graph illustrating an exemplary method for predicting wafer deformation using an equipment for predicting wafer deformation according to an embodiment.

FIG. 11, FIG. 12, FIG. 13 and FIG. 14 illustrate an example of using an equipment for predicting wafer deformation according to an embodiment.

FIG. 15 and FIG. 16 illustrate an example of using an equipment for predicting wafer deformation according to an embodiment.

FIG. 17 is a flowchart of a method for predicting wafer deformation using an equipment for predicting wafer deformation according to an embodiment.

### DETAILED DESCRIPTION OF THE EMBODIMENTS

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present disclosure is not limited to the illustrated sizes and thicknesses.

In addition, unless explicitly described to the contrary, the words “comprise” and “include” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, sequential numbers such as first and second are used to distinguish a certain component from another component that is the same or similar to the certain component, and are not necessarily intended to refer to a specific component. Accordingly, a component referred to as a first component in a particular portion of the specification may be referred to as a second component in another portion of the specification.

In addition, throughout the specification, a singular reference to a component includes references to a plurality of these components, unless specifically stated to the contrary.

Hereinafter, an equipment for predicting wafer deformation according to embodiments of the present disclosure will be described with reference to the drawings.

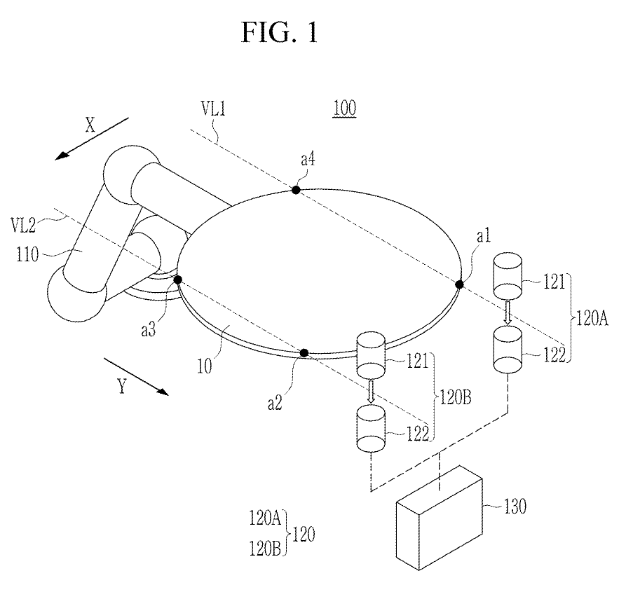

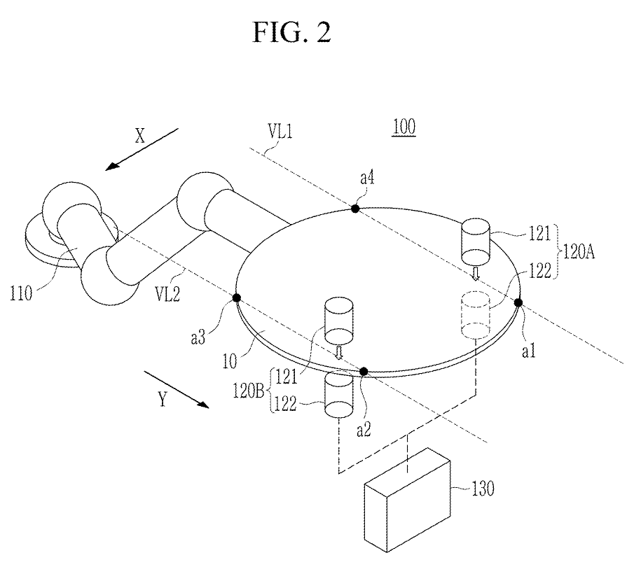

FIG. 1, FIG. 2 and FIG. 3 illustrate an operation example of an equipment for predicting wafer deformation according to an embodiment.

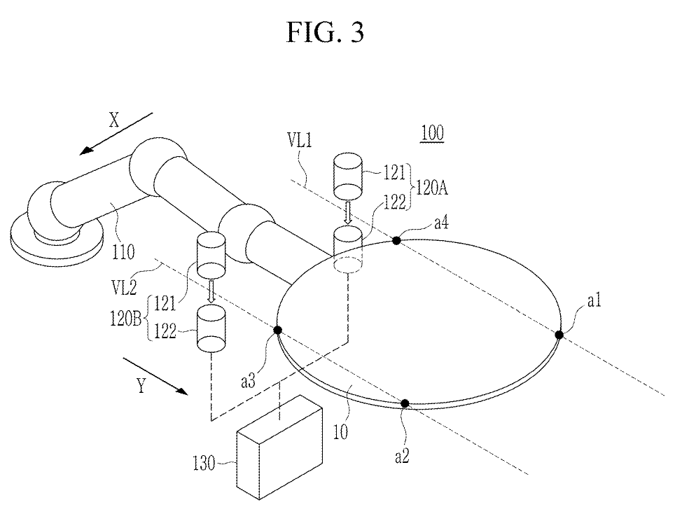

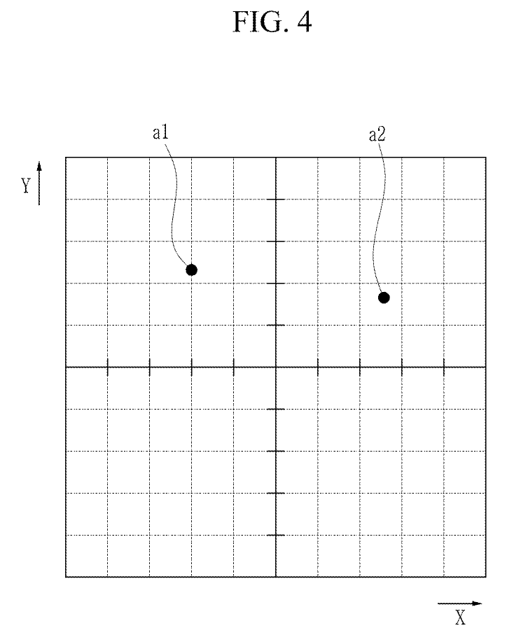

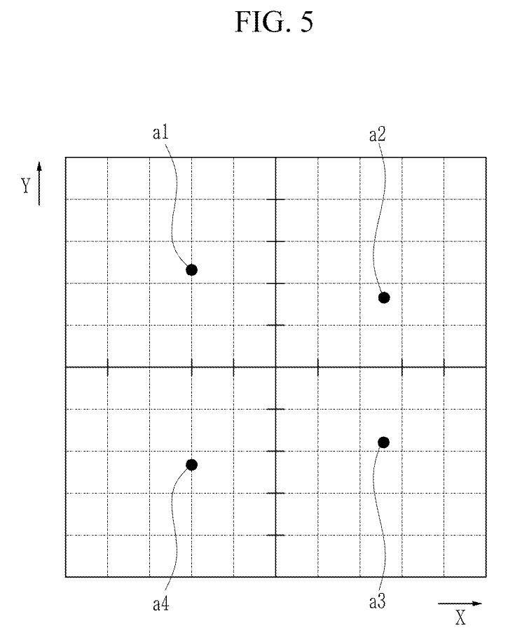

FIG. 4 and FIG. 5 show the positions of edge points of the wafer projected onto a coordinate plane.

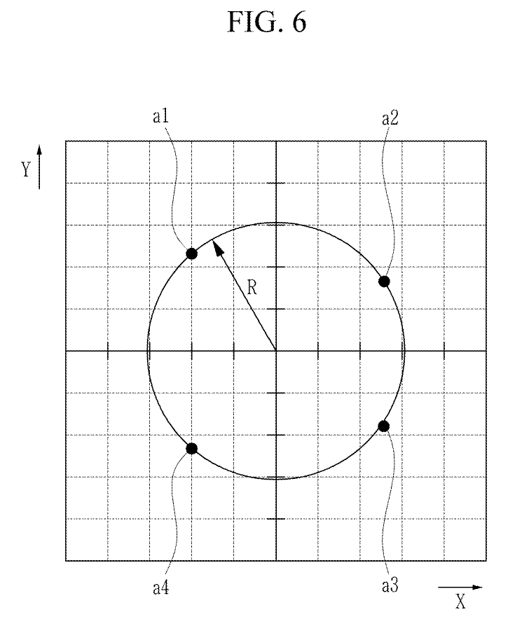

FIG. 6 shows a predicted plane form of the wafer and a derived exemplary feature value.

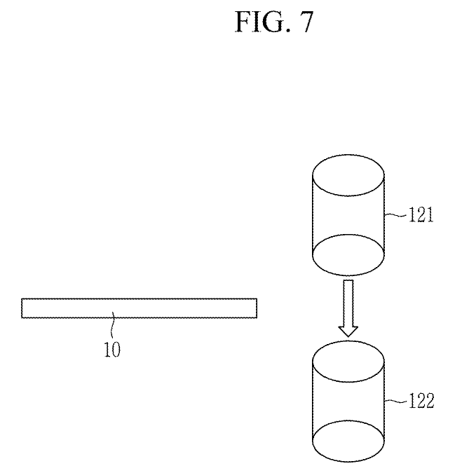

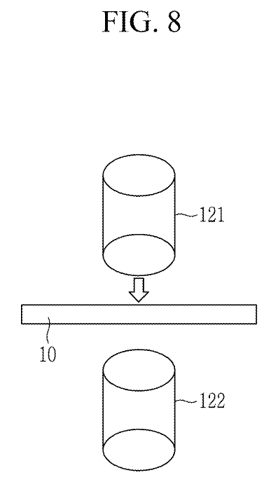

FIG. 7 and FIG. 8 illustrate a method for recognizing edge points of the wafer by a sensor unit according to an embodiment.

An equipment for predicting wafer deformation 100 according to an embodiment may predict a deformation of a wafer 10. For example, the equipment for predicting wafer deformation 100 may predict whether the wafer 10 is deformed, its deformed form, feature values, etc.

An equipment for predicting wafer deformation 100 according to an embodiment includes a transport unit 110, a sensor unit 120, and a control unit 130.

The transport unit 110 transports the wafer 10, and the wafer 10 may pass through the sensor unit 120 during transport. Additionally, the transport unit 110 may transport the wafer 10 that has passed through the sensor unit 120 to a process chamber and return the wafer 10 that has been discharged from the process chamber. The transport unit 110 may directly transport the wafer 10 to the process chamber and return it from the process chamber, or may transport the wafer 10 to the process chamber and return it from the process chamber via another component (e.g., another chamber).

The transport unit 110 may be positioned, for example, at least one of between an Equipment Front End Module (EFEM) and a load lock, between a load lock and a transfer module, and between a transfer module and a process chamber. An EFEM may perform a role of loading and aligning the wafer 10. A load lock may be used to change or regulate a pressure between an EFEM and a transfer module to a vacuum. A transfer module may perform a role of transferring the wafer 10 to a process chamber, transferring the wafer 10 between process chambers, and returning the wafer 10 that has completed processing to a load lock. In a process chamber, processes required for the wafer 10 is performed, and a process chamber may be a chamber in which the wafer 10 is substantially deformed(warped) due to temperature changes within a process chamber, temperature changes between process chambers, etc.

The transport unit 110 may include a robot arm. However, the transport unit 110 may include other transport equipments such as a rail.

The sensor unit 120 may recognize a plurality of edge points a1, a2, a3, a4 of the wafer 10. The sensor unit 120 may recognize at least three edge points of the wafer 10 to predict a plane form of the wafer 10. In the present disclosure, the word ‘form’ is used to mean both shape and size.

The sensor unit 120 may be positioned on a movement path of the wafer 10 by the transport unit 110. The sensor unit 120, like the transport unit 110, may be positioned at least one of between an Equipment Front End Module (EFEM) and a load lock, between a load lock and a transfer module, and between a transfer module and a process chamber.

In an embodiment, the position of the sensor unit 120 may be fixed, and the sensor unit 120 may recognize edge points of the wafer 10 moved by the transport unit 110 and passing through the sensor unit 120. However, the sensor unit 120 may recognize edge points of the wafer 10 by moving so that the wafer 10 whose position is fixed pass through the sensor unit 120.

In an embodiment, the sensor unit 120 may include a first sensor unit 120A and a second sensor unit 120B spaced apart in a direction intersecting a Y direction, which is a transport direction of the wafer 10, for example, in a X direction perpendicular to the Y direction. The first sensor unit 120A may recognize a first edge point a1 and a fourth edge point a4 of the wafer 10 that passes through the first sensor unit 120A and spaced apart in the Y direction. The second sensor unit 120B may recognize a second edge point a2 and a third edge point a3 of the wafer 10 that passes through the second sensor unit 120B and spaced apart in the Y direction. A first virtual line VL1, which connects the first edge point a1 and the fourth edge point a4, and a second virtual line VL2, which connects the second edge point a2 and the third edge point a3, may each be extended in the Y direction. The first virtual line VL1 and the second virtual line VL2 may be spaced apart in the X direction and may be parallel. As the positions of the first sensor unit 120A and the second sensor unit 120B are fixed, the interval between the first virtual line VL1 and the second virtual line VL2 may be fixed.

Referring to FIG. 7 and FIG. 8, the sensor unit 120 may include a light transmitter 121 for transmitting light and a light receiver 122 for receiving the light transmitted from the light transmitter 121. The sensor unit 120 may recognize the plurality of edge points a1, a2, a3, a4 of the wafer 10 based on whether the light receiver 122 receives the light depending on a presence of the wafer 10 between the light transmitter 121 and the light receiver 122. When the wafer 10 does not exist between the light transmitter 121 and the light receiver 122, the light receiver 122 may receive the light transmitted from the light transmitter 121 (see FIG. 7). When the wafer 10 exists between the light transmitter 121 and the light receiver 122, the light receiver 122 may not receive the light transmitted from the light transmitter 121 (see FIG. 8). The sensor unit 120 may output whether the light receiver 122 receives light as a digital signal value. For example, when the light receiver 122 receives the light transmitted from the light transmitter 121, the sensor unit 120 may output digital signal 1, and when the light receiver 122 does not receive light, the sensor unit 120 may output digital signal 0.

However, the sensor unit 120 may be composed of another type of sensor capable of recognizing the edge points a1, a2, a3, a4 of the wafer 10. Alternatively, the sensor unit 120 may be configured to recognize positions of edge points a1, a2, a3, a4 of the wafer 10.

The control unit 130 may receive the signal output by the sensor unit 120. The control unit 130 projects the positions of the plurality of edge points a1, a2, a3, a4 of the wafer 10 recognized by the sensor unit 120 onto a coordinate plane, and may predict a plane form of the wafer 10 based on the projected positions of the plurality of edge points a1, a2, a3, a4 of the wafer 10.

In an embodiment, the control unit 130 may project the positions of the plurality of edge points a1, a2, a3, a4 of the wafer 10 onto a coordinate plane within the control unit 130 by using data including at least one of a movement speed and a movement trajectory of the wafer 10, along with a point of time at which the sensor unit 120 recognizes each of the edge points a1, a2, a3, a4 of the wafer 10. The point of time when the sensor unit 120 recognizes the edge points a1, a2, a3, a4 of the wafer 10 may correspond to a point of time when the sensor unit 120 outputs a signal (e.g., digital signal 0 or 1). For example, when the wafer 10 moves linearly along the Y direction, the control unit 130 may project the positions of the plurality of edge points a1, a2, a3, a4 of the wafer 10 onto the coordinate plane by using an output time of each signal output by the sensor unit 120 and the movement speed of the wafer 10. For another example, when the wafer 10 does not move linearly, the control unit 130 may project the positions of the plurality of edge points a1, a2, a3, a4 of the wafer 10 onto the coordinate plane using the output time of each signal output by the sensor unit 120, the movement speed and the movement trajectory of the wafer 10.

In an embodiment, the control unit 130 may predict the plane form of the wafer 10 by circle interpolation based on the positions of the plurality of edge points a1, a2, a3, a4 of the wafer 10. For example, the control unit 130 may predict the plane form of the wafer 10 by circular interpolation based on the positions of three or four (e.g., in the case of an isotropic circular wafer) edge points a1, a2, a3, a4 of the wafer 10.

In an embodiment, the control unit 130 may predict the plane form of the wafer 10 by closed loop interpolation based on the positions of the plurality of edge points a1, a2, a3, a4 of the wafer 10. For example, the control unit 130 may predict the plane form of the wafer 10 by closed loop interpolation based on the positions of four or more edge points a1, a2, a3, a4 of the wafer 10.

Furthermore, the control unit 130 may extract feature values of the wafer 10 from the predicted plane form of the wafer 10. For example, the control unit 130 may derive a radius of the wafer 10 from the predicted plane form of the wafer 10 by circular interpolation. Alternatively, the control unit 130 may derive at least one of a length of the major axis and a length of the minor axis of the wafer 10 from the predicted plane form of the wafer 10 by closed loop interpolation.

In case when height data at each point of the wafer 10 may be additionally input to the control unit 130, the control unit 130 may also predict a 3-dimensional shape of the wafer 10 by combining the height data at each point of the wafer 10 with the predicted plane form.

Optionally, the control unit 130 may also perform an additional function of aligning the wafer 10 based on the positions of the plurality of edge points a1, a2, a3, a4 of the wafer 10. That is, the control unit 130 may predict the deformation of the wafer 10 based on the positions of the plurality of edge points a1, a2, a3, a4 of the wafer 10 and simultaneously perform alignment of the wafer 10.

An operation example of the equipment for predicting wafer deformation 100 during the transport of the wafer 10 is examined step by step as follows. First, referring to FIG. 1 and FIG. 2, the wafer 10 is transported by the transport unit 110, and the first edge point a1 passes through the first sensor unit 120A, and the second edge point a2 passes through the second sensor unit 120B. The control unit 130 projects the positions of the first edge point a1 and the second edge point a2 onto the coordinate plane (see FIG. 4). For example, the control unit 130 may set the first edge point a1 as a reference point (in the drawing, the position of the reference point is depicted differently from the origin), set the X coordinate (coordinate in the X direction) of the second edge point a2 through the fixed interval between the first virtual line VL1 and the second virtual line VL2 (which may correspond to the interval between the light transmitted from the first sensor unit 120A and the second sensor unit 120B), and set the Y coordinate (coordinate in the Y direction) of the second edge point a2 through an output time of the digital signal 0 by each of the first sensor unit 120A and the second sensor unit 120B and the movement speed of the wafer 10. Next, referring to FIG. 3, the third edge point a3 of the wafer 10 passes through the second sensor unit 120B, and the fourth edge point a4 passes through the first sensor unit 120A. The control unit 130 projects the positions of the third edge point a3 and the fourth edge point a4 onto the coordinate plane (see FIG. 5). For example, the control unit 130 may set the X coordinate of the third edge point a3 to be the same as the second edge point a2, and set the Y coordinate of the third edge point a3 through the duration of digital signal 0 of the second sensor unit 120B (the time taken for the digital signal 1 to be output again after the digital signal 0 is output from the second sensor unit 120B) and the movement speed of the wafer 10. Additionally, the control unit 130 may set the X coordinate of the fourth edge point a4 to be the same as the first edge point a1, and may set the Y coordinate of the fourth edge point a4 through the duration of digital signal 0 of the first sensor unit 120A and the movement speed of the wafer 10. Next, referring to FIG. 6, the control unit 130 may predict the plane form of the wafer 10 by circular interpolation based on the positions of the plurality of edge points a1, a2, a3, a4, and derive the radius R of the wafer 10 as a feature value.

Meanwhile, deformations (warpage) such as bow and warp may occur to the wafer. When the wafer is moved to a warpage measurement equipment to measure the warpage of the wafer, a lot of TAT (Turn Around Time) is required due to the movement, input, alignment, and measurement of the wafer, which may cause a decrease in productivity. To minimize the decrease in productivity, a method of measuring the warpage of only some of the wafers could be considered, but in this case, the deformation of the wafers due to warpage may not be perfectly detected, and thus, the wafer may be fractured. If the inside of the equipment is contaminated due to the fractured wafer, it may have a significant impact on productivity due to a production stoppage.

According to the present disclosure, the deformation of the wafer 10 may be predicted in real time by simply passing the wafer 10 through the sensor unit 120 while performing the already existing process, without an additional process of putting the wafer 10 into a separate equipment, aligning the wafer 10, and then measuring warpage. Therefore, the deformation of the wafer 10 may be predicted without increased time and cost due to the additional process.

In addition, according to the present disclosure, it is possible to predict a deformation for all wafers 10 before the wafers 10 are put into a process chamber, and determine whether to put the wafers 10 into a subsequent process based on whether each wafer 10 is deformed, a degree of deformation, etc. By selectively putting the wafers 10 into the subsequent process depending on a degree of deformation of the wafer 10, fractures of the wafers 10 may be prevented, and equipment contamination and a production stoppage caused by fractured wafers may be prevented.

In addition, the present disclosure may also be utilized in a way to predict the form of the wafer 10 from which data having a specific form (e.g., positions of edge points in a coordinate plane, predicted plane form, feature values, etc.) is output by learning data of the wafer 10 having the specific form through machine learning.

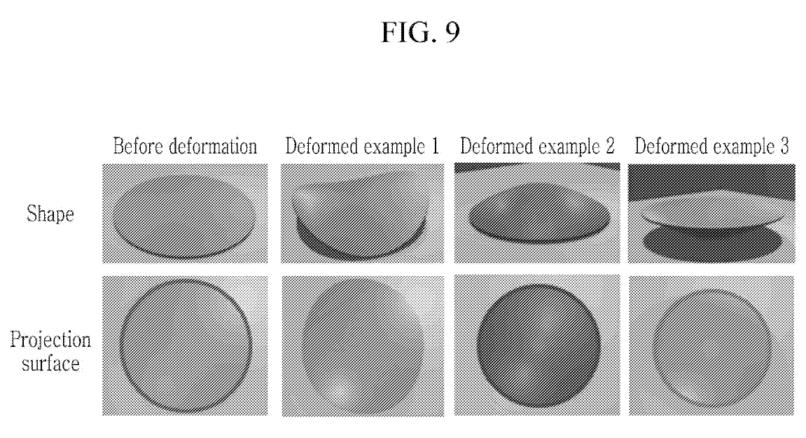

FIG. 9 shows exemplary shapes of wafers and their projection surfaces.

Before deformation, a wafer may have a circular plate shape. During a process, the wafer may experience a deformation (warpage) due to bending and twisting. For example, the wafer may be deformed into various shapes, such as a saddle shape as shown in deformed example 1, a dome shape as shown in deformed example 2, a bowl shape as shown in deformed example 3, a smile shape with both sides raised, and a crying shape with both sides lowered. When the wafer is deformed into a saddle shape, its projection surface shows an ellipse, and when it is deformed into a dome or ball shape, its projection surface shows a reduced circle. According to the present disclosure, wafer deformation may be predicted by utilizing the fact that each projection surface exhibits a different form (shape and/or size) depending on the deformed form.

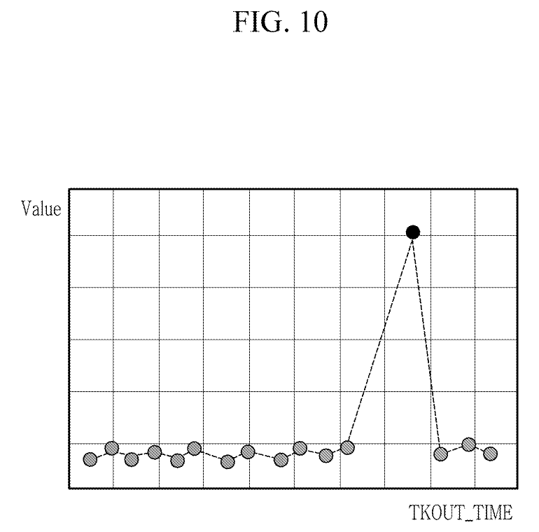

FIG. 10 is a graph illustrating an exemplary method for predicting wafer deformation using an equipment for predicting wafer deformation according to an embodiment.

The horizontal axis of the graph represents the time at which each wafer 10 is released from a facility (track out time), and the vertical axis represents the feature value of each wafer 10. The control unit 130 may be loaded with a numerical feature value for the predicted plane form of the wafer 10. For example, the radius value of the wafer 10 may be loaded into the control unit 130. Since undeformed wafers exhibit similar feature values and deformed wafers exhibit different values, deformed wafers may be detected by comparing the feature values loaded into the control unit 130.

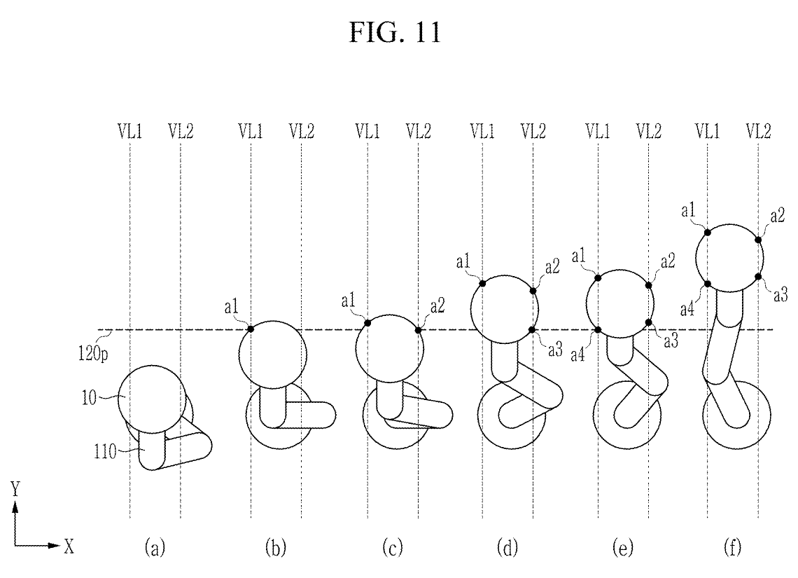

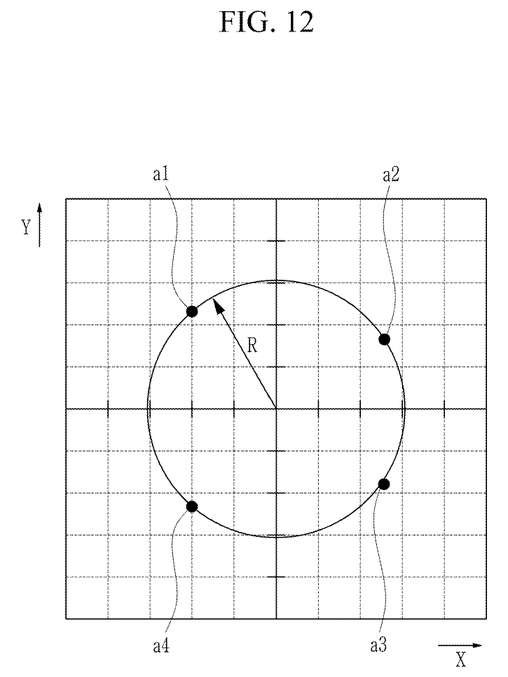

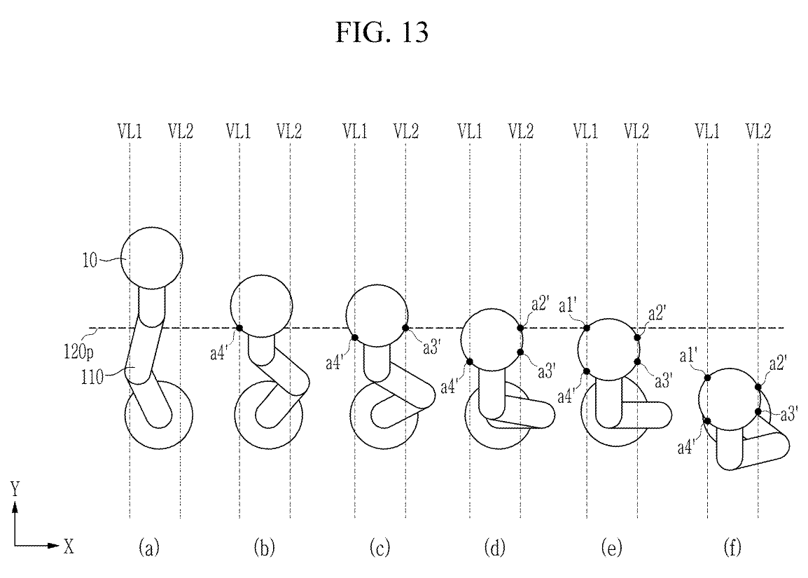

FIG. 11, FIG. 12, FIG. 13 and FIG. 14 illustrate an example of using an equipment for predicting wafer deformation according to an embodiment.

An equipment for predicting wafer deformation according to an embodiment may be utilized to compare the form of the wafer 10 before and after process.

The (a), (b), (c), (d), (e) and (f) of FIG. 11 illustrate the wafer 10 passing through the sensor unit 120 during the transport of the wafer 10 step by step.

FIG. 12 shows the predicted pre-process plane form of the wafer 10 and the derived exemplary feature value.

The (a), (b), (c), (d), (e) and (f) of FIG. 13 illustrate the wafer 10 passing through the sensor unit 120 during return of the wafer step by step.

FIG. 14 shows the predicted post-process plane form of the wafer 10 and the derived exemplary feature value. For comparison with the wafer 10 before processing, the predicted pre-process plane form is also shown with a dotted line.

In FIG. 11 and FIG. 13, only the position 120p of the sensor unit 120 in the Y direction is depicted with a dotted line. Additionally, the control unit 130 is omitted.

As described above, the transport unit 110 may transport the wafer 10 to the process chamber and return the wafer 10 from the process chamber. During the transport of the wafer 10, the wafer 10 may be transported in the Y direction and pass through the sensor unit 120, and during the return of the wafer 10, the wafer 10 may be returned in the opposite direction of the Y direction (hereinafter, may be referred to as -Y direction) and pass through the sensor unit 120.

The sensor unit 120 may recognize a plurality of pre-process edge points a1, a2, a3, a4 of the wafer 10 during the transport of the wafer 10 by the transport unit 110, and may recognize a plurality of post-process edge points a1’, a2’, a3’, a4’ of the wafer 10 during the return of the wafer 10 by the transport unit 110.

In an embodiment, the sensor unit 120 sequentially recognizes a first pre-process edge point a1, a second pre-process edge point a2, a third pre-process edge point a3, and a fourth pre-process edge point a4 of the wafer 10 during transport of the wafer 10 by the transport unit 110, and sequentially recognizes a fourth post-process edge point a4’, a third post-process edge point a3’, a second post-process edge point a2’, and a first post-process edge point a1’ of the wafer 10 during return of the wafer 10 by the transport unit 110.

The control unit 130 may project positions of the plurality of pre-process edge points a1, a2, a3, a4 recognized by the sensor unit 120 onto a coordinate plane, and predict a pre-process plane form of the wafer 10 based on the projected positions of the plurality of pre-process edge points a1, a2, a3, a4. In addition, the control unit 130 may project positions of the plurality of post-process edge points a1’, a2’, a3’, a4’ recognized by the sensor unit 120 onto the coordinate plane, and predict a post-process plane form of the wafer 10 based on the projected positions of the plurality of post-process edge points a1’, a2’, a3’, a4’.

In an embodiment, the control unit 130 may predict the pre-process plane form of the wafer 10 through four pre-process edge points a1, a2, a3, a4, and may predict the post-process plane form of the wafer 10 through four post-process edge points a1’, a2’, a3’, a4’. For example, the control unit 130 may predict the pre-process or post-process plane form of the wafer 10 by circular interpolation based on the positions of the pre-process edge points a1, a2, a3, a4, or post-process edge points a1’, a2’, a3’, a4’ of the wafer 10.

Furthermore, the control unit 130 may extract a pre-process feature value and a post-process feature value of the wafer 10 from the plane form of the wafer 10 and/or compare the pre-process feature value and the post-process feature value. For example, the control unit 130 may extract and compare the pre-process radius R and post-process radius R’ of the wafer 10 from the plane form of the wafer 10.

By comparing the form of the wafer 10 before and after process, the stress applied to wafer 10 due to the process may be monitored, and the form of the wafer 10 after process may be predicted.

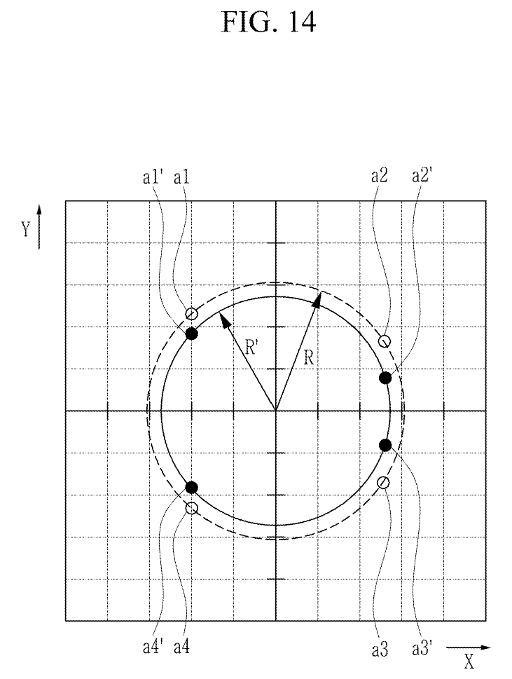

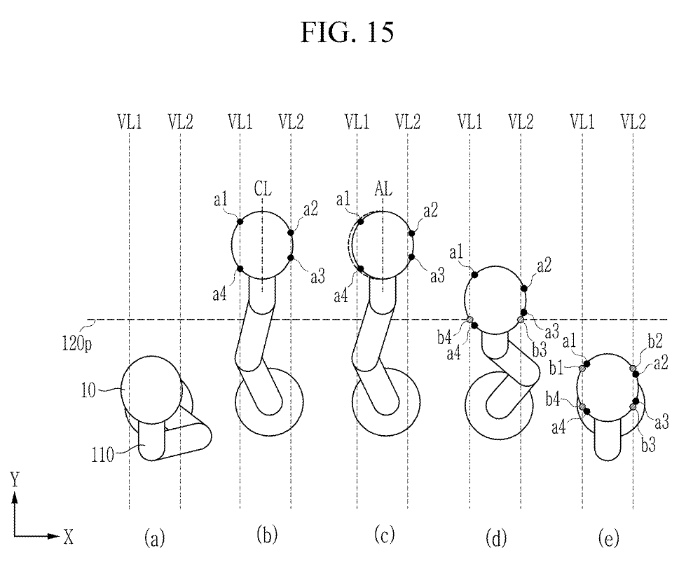

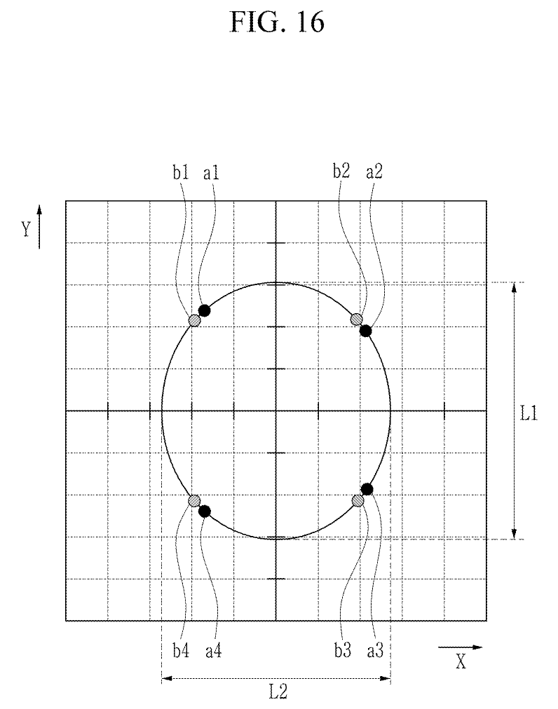

FIG. 15 and FIG. 16 illustrate an example of the using an equipment for predicting wafer deformation according to an embodiment.

An equipment for predicting wafer deformation according to an embodiment may be utilized for more sophisticated wafer deformation prediction. For example, an equipment for predicting wafer deformation may be utilized for anisotropic circular (e.g., elliptical) wafer measurement.

The (a), (b), (c), (d), (e) and (f) of FIG. 15 illustrate the wafer 10 passing through the sensor unit 120 during the transport of the wafer 10 step by step.

FIG. 16 shows the predicted plane form of the wafer 10 and derived exemplary feature values.

In FIG. 15, only the position 120p in the Y direction of the sensor unit 120 is depicted with a dotted line. Additionally, control unit 130 is omitted.

The transport unit 110 may pass the wafer 10 through the sensor unit 120 multiple times. For example, the transport unit 110 may move the wafer 10 in the Y direction, move the wafer 10 in the -Y direction, and then transport the wafer 10 in the Y direction. The wafer 10 may pass through the sensor unit 120 during moving in the Y direction by the transport unit 110 and during moving in the -Y direction. The wafer 10 that is then transported may be placed into a process chamber. In the present disclosure, the wafer 10 transported by the transport unit 110 is described as an example with reference to this, but it is of course also possible for the wafer returned by the transport unit 110 to pass through the sensor unit 120 multiple times after being returned.

The transport unit 110 may further move the wafer 10 so that the sensor unit 120 recognizes a plurality of second edge points b1, b2, b3, b4 distinct from a plurality of first edge points a1, a2, a3, a4 while the wafer 10 is being moved in the -Y direction, after the sensor unit 120 recognizes the first edge points a1, a2, a3, a4 and before the sensor unit 120 recognizes the second edge points b1, b2, b3, b4. For example, the transport unit 110 may move the wafer 10 in a direction intersecting the Y direction, for example, in the X direction perpendicular to the Y direction. However, the transport unit 110 may also move the wafer 10 in other ways, such as rotational movement, rotational and linear movement. If necessary, the transport unit 110 may be fixed and the sensor unit 120 may be implemented to move to recognize the plurality of second edge points b1, b2, b3, b4 that are distinct from the plurality of first edge points a1, a2, a3, a4 while the wafer 10 is being moved in the -Y direction.

Moving the wafer 10 in the X direction may be a movement to align the wafer 10 for process. To align the wafer 10, the control unit 130 may derive a center position (e.g., center line CL or center point) of the wafer 10 in the X direction based on positions of the plurality of first edge points a1, a2, a3, a4 recognized by the sensor unit 120. Thereafter, the transport unit 110 may move the wafer 10 in the X direction to move the derived center position of the wafer 10 to a pre-determined alignment position (e.g., alignment line AL or alignment point) (see (b) and (c) of FIG. 15). It may be possible to secure additional plane coordinates of edge points while aligning for transport of the wafer 10.

The sensor unit 120 may recognize a plurality of first edge points a1, a2, a3, a4 of the wafer 10 while the wafer 10 moves in the Y direction, and may recognize a plurality of second edge points b1, b2, b3, b4 of the wafer 10 while the wafer 10 moves in the opposite direction of the Y direction. The first edge points a1, a2, a3, a4 may be edge points recognized primarily by the sensor unit 120, and the second edge points b1, b2, b3, b4 may be edge points recognized secondarily by the sensor unit 120.

In an embodiment, the sensor unit 120 may sequentially recognize the first-first edge point a1, the first-second edge point a2, the first-third edge point a3, and the first-fourth edge point a4 of the wafer 10 while the wafer 10 is moving in the Y direction. In addition, during movement of the wafer 10 in the -Y direction, the second-fourth edge point b4 and the second-third edge point b3 of the wafer 10 may be recognized simultaneously, and then the second-second edge point b2 and the second-first edge point b1 of the wafer 10 may be recognized simultaneously by the sensor unit 120 (when the wafer 10 is aligned and then moved in the -Y direction).

The control unit 130 may project the positions of the plurality of first edge points a1, a2, a3, a4 and the plurality of second edge points b1, b2, b3, b4 recognized by the sensor unit 120 onto a coordinate plane, and predict a plane form of the wafer 10 based on the projected positions of the plurality of first edge points a1, a2, a3, a4 and the plurality of second edge points b1, b2, b3, b4.

In an embodiment, the control unit 130 may predict the plane form of the wafer 10 through four first edge points a1, a2, a3, a4 and four second edge points b1, b2, b3, b4. For example, the control unit 130 may predict the plane form of the wafer 10 by closed loop interpolation based on the positions of the plurality of edge points a1, a2, a3, a4, b1, b2, b3, b4 of the wafer 10.

Further, the control unit 130 may extract feature values of the wafer 10 from the predicted plane form of the wafer 10. For example, the control unit 130 may derive at least one of the length L1 of the major axis and the length L2 of the minor axis of the wafer 10 from the plane form of the wafer 10.

The deformation of the wafer 10 may be predicted more precisely based on the positions of a number of edge points a1, a2, a3, a4, b1, b2, b3, b4.

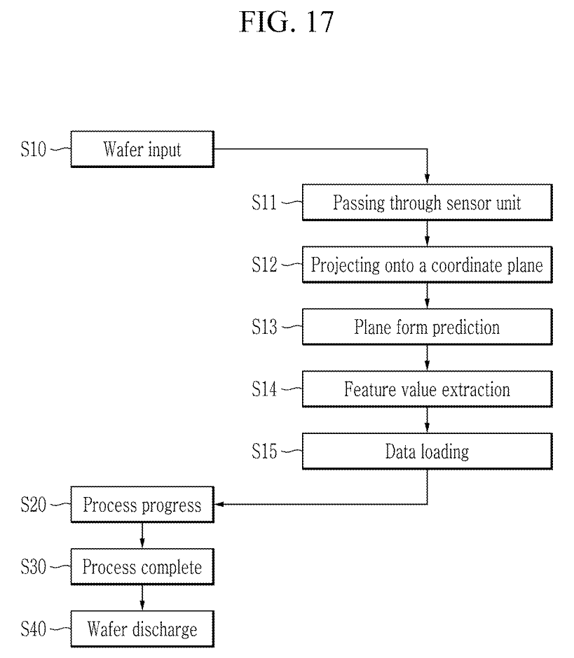

FIG. 17 is a flowchart of a method for predicting wafer deformation using an equipment for predicting wafer deformation according to an embodiment.

The wafer deformation prediction method according to the present disclosure includes a step S11 of passing a wafer 10 through a sensor unit 120, a step S12 of projecting positions of a plurality of edge points a a1, a2, a3, a4 of the wafer 10 recognized by the sensor unit 120 onto a coordinate plane, and a step S13 of predicting a plane form of the wafer 10 based on the positions of the plurality of edge points a1, a2, a3, a4 of the wafer 10 projected onto the coordinate plane.

In an embodiment, the wafer deformation prediction may be performed after the wafer is put into a facility that may include an equipment for predicting wafer deformation according to the present disclosure but before process begins. That is, the wafer deformation prediction may be performed between a step S10 of putting the wafer into the facility and a step S20 of process progress. Therefore, a process may be selectively performed on each wafer depending on whether the wafer 10 is deformed and the degree of deformation. After the process completion step S30, a step S40 of discharging the wafer 10 to the outside of the facility may be performed.

In an embodiment, the wafer deformation prediction may be performed in a step between the first process and the second process, and the second process may be performed only on wafers that are determined not to have been deformed after the first process. In another embodiment, the wafer deformation prediction may be performed before and after the first process respectively, to monitor the stress applied to the wafer due to the first process and to predict the deformation of the wafer according to the first process.

In an embodiment, the step S13 of predicting a plane form of the wafer based on the positions of the plurality of edge points a1, a2, a3, a4 of the wafer 10 may be performed by circular interpolation or closed loop interpolation.

In an embodiment, a step S14 of extracting a feature value of the wafer 10 from the predicted plane form of the wafer 10 may be additionally performed. For example, in step S14 of extracting a feature value of the wafer 10, the radius of the wafer 10 may be derived as a feature value from the plane form of the wafer 10, or at least one of the length of the major axis and the length of the minor axis may be derived as a feature value.

Furthermore, a step S15 of loading feature values of the wafer 10 may be additionally performed. Since undeformed wafers exhibit similar feature values and deformed wafers exhibit different values, deformed wafers may be detected by comparing the loaded feature values.

Although the embodiment of the present disclosure has been described in detail above, the scope of the present disclosure is not limited thereto, and various modifications and improvements of a person of an ordinary skill in the art utilizing the basic concept of the present disclosure defined in the following claims also fall within the scope of the present disclosure.

Additionally, the embodiments of the present disclosure are not independent of each other and may be implemented in combination with each other unless specifically contradictory. Therefore, the combined embodiment of the present disclosure should also be considered as included in the present disclosure.

What is claimed is:

1. An equipment for predicting wafer deformation, the equipment comprising:
a transport unit that transports a wafer;
a sensor unit that recognizes a plurality of edge points of the wafer being transported by the transport unit; and
a control unit that projects positions of the plurality of edge points of the wafer recognized by the sensor unit onto a coordinate plane, and predicts a plane form of the wafer based on the positions of the plurality of edge points of the wafer projected onto the coordinate plane.

2. The equipment for predicting the wafer deformation of claim 1, wherein the sensor unit includes a first sensor unit and a second sensor unit spaced apart in a second direction intersecting a first direction, which is a transport direction of the wafer by the transport unit.

3. The equipment for predicting the wafer deformation of claim 2, wherein the first sensor unit recognizes a first edge point and a second edge point of the wafer passing through the first sensor unit among the plurality of edge points and spaced in the first direction, and the second sensor unit recognizes a third edge point and a fourth edge point of the wafer passing through the second sensor unit among the plurality of edge points and spaced in the first direction.

4. The equipment for predicting the wafer deformation of claim 1, wherein the sensor unit includes a light transmitter that transmits light and a light receiver that receives the light transmitted from the light transmitter, and recognizes the plurality of edge points of the wafer based on whether the light receiver receives the light depending on a presence of the wafer between the light transmitter and the light receiver.

5. The equipment for predicting the wafer deformation of claim 1, wherein the control unit projects the positions of the plurality of edge points of the wafer onto the coordinate plane using data including a point of time at which the sensor unit recognizes each of the plurality of edge points of the wafer and a movement speed of the wafer.

6. The equipment for predicting the wafer deformation of claim 5, wherein the control unit projects the positions of the plurality of edge points of the wafer onto the coordinate plane using the data that further including a movement trajectory of the wafer.

7. The equipment for predicting the wafer deformation of claim 1, wherein the sensor unit recognizes at least three edge points of the wafer.

8. The equipment for predicting the wafer deformation of claim 1, wherein the control unit predicts the plane form of the wafer by circle interpolation based on the positions of the plurality of edge points of the wafer.

9. The equipment for predicting the wafer deformation of claim 8, wherein the control unit derives a radius of the wafer from the predicted plane form of the wafer.

10. The equipment for predicting the wafer deformation of claim 1, wherein the control unit predicts the plane form of the wafer by closed loop interpolation based on the positions of the plurality of edge points of the wafer.

11. The equipment for predicting the wafer deformation of claim 10, wherein the control unit derives at least one of a length of a major axis and a length of a minor axis of the wafer from the predicted plane form of the wafer.

12. The equipment for predicting the wafer deformation of claim 1, wherein the transport unit includes a robot arm.

13. The equipment for predicting the wafer deformation of claim 1, wherein a position of the sensor unit is fixed.

14. An equipment for predicting wafer deformation, the equipment comprising:
a transport unit that transports a wafer to a process chamber and returns the wafer discharged from the process chamber;
a sensor unit that recognizes a plurality of pre-process edge points of the wafer during transport of the wafer by the transport unit and a plurality of post-process edge points of the wafer during return of the wafer by the transport unit; and
a control unit that projects positions of the plurality of pre-process edge points of the wafer recognized by the sensor unit onto a coordinate plane and predicts a pre-process plane form of the wafer based on the positions of the plurality of pre-process edge points of the wafer projected onto the coordinate plane, and projects positions of the plurality of post-process edge points of the wafer recognized by the sensor unit onto the coordinate plane and predicts a post-process plane form of the wafer based on the positions of the plurality of post-process edge points of the wafer projected onto the coordinate plane.

15. The equipment for predicting the wafer deformation of claim 14, wherein the wafer is transported in a first direction and passes through the sensor unit during the transport of the wafer, and the wafer is returned in a second direction, which is an opposite direction to the first direction, and passes through the sensor unit during the return of the wafer.

16. The equipment for predicting the wafer deformation of claim 15, wherein the sensor unit includes a first sensor unit and a second sensor unit spaced apart in the second direction.

17. An equipment for predicting wafer deformation, the equipment comprising:
a transport unit that moves a wafer in a first direction, moves the wafer in a second direction opposite to the first direction, and then transports the wafer in the first direction;
a sensor unit that recognizes a plurality of first edge points of the wafer during the wafer is moved in the first direction by the transport unit, and recognizes a plurality of second edge points of the wafer during the wafer is moved in the second direction by the transport unit; and
a control unit that projects positions of the plurality of first edge points of the wafer and the plurality of second edge points of the wafer recognized by the sensor unit onto a coordinate plane, and predicts a plane form of the wafer based on the positions of the plurality of first edge points of the wafer and the plurality of second edge points of the wafer projected onto the coordinate plane;
wherein the wafer passes through the sensor unit during moving in the first direction by the transport unit and during moving in the second direction by the transport unit.

18. The equipment for predicting the wafer deformation of claim 17, wherein the transport unit further moves the wafer in a third direction intersecting the first direction, so that the sensor unit recognizes the plurality of second edge points that are distinct from the plurality of first edge points during moving of the wafer in the second direction, after the sensor unit recognizes the plurality of first edge points and before the sensor unit recognizes the plurality of second edge points.

19. The equipment for predicting the wafer deformation of claim 18, wherein, the control unit derives a center position of the wafer in the third direction based on the positions of the plurality of first edge points of the wafer recognized by the sensor unit, and the transport unit moves the wafer in the third direction to move the derived center position of the wafer to a predetermined alignment position.

20. The equipment for predicting the wafer deformation of claim 17, wherein the sensor unit includes a first sensor unit and a second sensor unit spaced in a third direction intersecting the first direction.
